(19) United States
(12) Patent Application Publication
(10) Pub. No.: US 2025/0212515 A1
(43) Pub. Date: Jun. 26, 2025

(54) DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventor: Bo ZHANG, Shenzhen (CN)

(73) Assignee: Shenzhen China Star Optoelectronics Semiconductor Display Technology Co., Ltd., Shenzhen (CN)

(21) Appl. No.: 18/900,798

(22) Filed: Sep. 29, 2024

(30) Foreign Application Priority Data
Dec. 20, 2023 (CN) 202311772490.2

(51) Int. Cl. H01L 27/12

(52) U.S. Cl. CPC H10D 86/60; H10D 86/0231; H10D 86/423

(57) ABSTRACT

The present invention relates to a display panel and its manufacturing method. The invention uses a lanthanide series element and scandium co-doped indium zinc oxide to prepare an oxide as the first active layer of the GOA region. The lanthanide series element suppresses the formation of excessive oxygen vacancies and serves as a conversion medium under blue light with low charge transfer transition energy. This greatly improves the stability of the thin-film transistor in the first active layer of the GOA region without affecting mobility. Scandium helps to suppress the formation of excessive oxygen vacancies, control carrier concentration, and maintain lattice matching, further enhancing the stability of the thin-film transistor in the GOA region.

### CROSS REFERENCE TO RELATED APPLICATIONS

This application claims the priority to Chinese Patent Application No. 202311772490.2, filed on Dec. 20, 2023. The entire disclosures of the above application are incorporated herein by reference.

### FIELD OF INVENTION

The present application relates to a field of display technologies, especially to a display panel and a manufacturing method thereof.

### BACKGROUND OF INVENTION

To achieve the next generation of large-sized, high-resolution, high-refresh-rate, narrow-bezel tablet displays, it is crucial to further develop oxide thin-film transistors (TFTs) with high mobility and high stability. Amorphous oxide semiconductors (AOS) have attracted significant attention due to their excellent performance, such as high carrier mobility with uniformity over large areas, low off-state current (Ioff), and a large optical bandgap. However, a severe threshold voltage shift (ΔVth) is observed when TFTs undergo negative gate electrode bias stress and continuous light exposure, even in negative bias illumination stability (NBIS). This issue persists for several days even after the stress is removed, severely limiting the further commercialization of AOS TFTs.

Typically, instability in stability tests like negative bias temperature stress (NBTS) is attributed to the inherent states of AOS materials. Recently, potential high-mobility AOS materials like indium oxide (In₂O₃) and indium zinc oxide (InZnO, IZO) have drawn attention. However, high-mobility IZO TFTs face challenges in controlling the high carrier concentration and oxygen vacancies within the IZO material, leading to negative threshold voltage (Vth) shifts and device stability issues. To improve the stability of AOS TFTs, reducing the concentration of oxygen vacancies (Vo) is the most commonly used method. While cation doping (which binds oxygen) and intentional oxygen supply methods (such as high-pressure annealing, oxygen-containing plasma treatment, ozone radical treatment, and ultra-high vacuum sputtering) can reduce oxygen vacancies, the improved threshold voltage shift remains too large to drive an active matrix display without compensation. Although J. Kim and H. Hosono have developed a wide-bandgap AOS, zinc gallate (ZnGaO), to improve AOS TFT's NBTS stability by widening the optical bandgap, ensuring the light excitation energy between the subgap state and the conduction band minimum (CBM) is greater than 3 eV, this method significantly reduces mobility. This is because the adjacent metal ions (Ga and Zn) have non-overlapping 4s orbitals, disrupting the electron transmission path in the amorphous state. Therefore, current AOS TFTs face a trade-off between high mobility and high stability.

### SUMMARY OF INVENTION

An objective of the present invention is to provide a display panel, a manufacturing method thereof, and a display device thereof, which can solve the issue of the conventional AOS TFT facing a trade-off between high mobility and high stability.

To solve the above issue, the present invention provides a display panel, comprising: a display region and a gate on array (GOA) region located on at least one side of the display region; wherein the display panel comprises: a substrate; and a first active layer disposed on the substrate and located on the GOA region; wherein ingredients of the first active layer, according to mole percent, comprise: indium zinc oxide ranging from 93 mol % to 99.5 mol %; lanthanide series element ranging from 0.5 mol % to 5 mol %; and scandium ranging from 0 mol % to 2 mol %.

Furthermore, the display panel further comprises: a first semiconductor layer disposed between the substrate and the first active layer, located in the GOA region, and disposed to correspond to the first active layer; a second active layer disposed in a same layer with the first semiconductor layer and located in the display region, wherein the second active layer comprises a second channel part and second conductive parts connected to two ends of the second channel part respectively; and a first electrode plate disposed in a same layer with the first semiconductor layer, located in the display region, and disposed on a side of the second active layer away from the first semiconductor layer; wherein material of the first semiconductor layer is the same as material of the second channel part, and material of the first electrode plate is the same as material of the second conductive parts.

Furthermore, the first active layer comprises a first channel part and first conductive parts connected to two ends of the first channel part respectively; the display panel further comprises: a first insulation layer disposed between the first semiconductor layer and the first active layer and disposed to correspond to the first semiconductor layer; a second insulation layer disposed on the first active layer and disposed to correspond to the first channel part; and a third insulation layer disposed on the second active layer and disposed to correspond to the second channel part; wherein material of the second insulation layer is the same as material of the third insulation layer.

Furthermore, the second insulation layer is disposed in a same layer with the third insulation layer.

Furthermore, the display panel further comprises: a first gate electrode disposed on the second insulation layer and disposed to correspond to the first channel part; and a second gate electrode disposed on the third insulation layer and disposed to correspond to the second channel part; wherein material of the first gate electrode is the same as material of the second gate electrode.

Furthermore, the first gate electrode is disposed in a same layer with the second gate electrode.

Furthermore, the display panel further comprises: an interlayer insulation layer covering the first gate electrode, the second gate electrode, the first active layer, and the second active layer; a first source electrode disposed on the interlayer insulation layer and electrically connected to one of the first conductive parts, and located in the GOA region; a first drain electrode disposed in a same layer with the first source electrode, electrically connected to another of the first conductive parts, and located in the GOA region; a second source electrode disposed in a same layer with the first source electrode, electrically connected to one of the second conductive parts, and located in the display region; a second drain electrode disposed in a same layer with the second source electrode, electrically connected to another of the second conductive parts, and located in the display region; and a second electrode plate disposed in a same layer with the first source electrode, disposed to correspond to the first electrode plate, and located in the display region; wherein material of the first source electrode, the first drain electrode, the second source electrode, the second drain electrode, and the second electrode plate is the same.

Furthermore, the display panel further comprises: a fourth insulation layer disposed between the second active layer and the third insulation layer and disposed to correspond to the second channel part; wherein material of the fourth insulation layer and the first insulation layer is the same, and the fourth insulation layer and the first insulation layer are disposed in a same layer.

To solve the above issue, the present invention provides a display panel manufacturing method, wherein a display panel comprises a display region and a GOA region located on at least one side of the display region, and the method comprises steps as follows: manufacturing a first active layer on a substrate of the GOA region, wherein ingredients of the first active layer, according to mole percent, comprise: indium zinc oxide ranging from 93 mol % to 99.5 mol %; lanthanide series element ranging from 0.5 mol % to 5 mol %; and scandium ranging from 0 mol % to 2 mol %.

Furthermore, the step of manufacturing a first active layer on a substrate of the GOA region comprises steps as follows: manufacturing a first semiconductor material layer on the substrate, manufacturing a first insulation material layer on the first semiconductor material layer, and manufacturing a first active material layer on the first insulation material layer; manufacturing a photoresist layer on the first active material layer by a half-tone mask process, wherein the photoresist layer comprises a first photoresist unit located in the GOA region, a second photoresist unit located in the display region, and a third photoresist unit located in the display region, a thickness of the first photoresist unit is greater than a thickness of the second photoresist unit, and the thickness of the second photoresist unit is greater than a thickness of the third photoresist unit; removing parts of the first active material layer and the first insulation material layer not covered by the first photoresist unit, the second photoresist unit and the third photoresist unit; first thinning the thicknesses of the first photoresist unit and the second photoresist unit, removing the third photoresist unit and a part of the first active material layer covered by the third photoresist unit, patterning the first semiconductor material layer to form a first semiconductor layer, a second active layer, and a first electrode plate; removing the first insulation material layer on the first electrode plate; second thinning the thickness of the first photoresist unit, removing the second photoresist unit and a part of the first active material layer covered by the second photoresist unit wherein the first active material layer covered by the first photoresist unit forms a first active layer, and peeling the first photoresist unit off.

The advantages of the present invention are as follows: the present invention uses a lanthanide series element and scandium co-doped indium zinc oxide to prepare an oxide as the first active layer of the GOA region. The lanthanide series element suppresses the formation of excessive oxygen vacancies and serves as a conversion medium under blue light with low charge transfer transition energy. This greatly enhances the stability of the thin-film transistor in the GOA region's first active layer without affecting mobility, enabling the GOA region's thin-film transistor to achieve both high mobility and high stability. Scandium, on the other hand, suppresses excessive oxygen vacancies, controls carrier concentration, and maintains lattice matching, further improving the stability of the thin-film transistor in the GOA region's first active layer, ensuring both high mobility and high stability.

The present invention adopts one half-tone mask process to fabricate the first semiconductor layer, second active layer, first electrode plate, first insulation layer, and first active layer, thereby reducing the number of masks, simplifying production procedures, and saving production costs.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may also acquire other figures according to the appended figures without any creative effort.

FIG. 1 is a schematic structural view of the display panel of the present invention; and

FIG. 2 to FIG. 9 are schematic view of products corresponding to steps of the display panel manufacturing method of the present invention.

### DESCRIPTION OF REFERENCE CHARACTERS

100, display panel; 101, display region; 102, GOA region;

1, substrate; 2, buffer layer; 3, first semiconductor layer; 4, first insulation layer; 5, first active layer; 6, second insulation layer; 7, first gate electrode; 8, interlayer insulation layer; 9, first source electrode; 10, first drain electrode; 11, second active layer; 12, third insulation layer; 13, second gate electrode; 14, second source electrode; 15, second drain electrode; 16, first electrode plate; 17, second electrode plate; 18, first light shielding layer; 19, second light shielding layer; 20, passivation layer; 21, conductive layer; 22, planarization layer; 23, pixel electrode; 24, pixel definition layer; 25, fourth insulation layer, 51, first channel part; 52, first conductive parts; 111, second channel part; 112, second conductive parts; 26, first semiconductor material layer; 27, first insulation material layer; 28, first active material layer; 29, photoresist layer; 291, first photoresist unit; 292, second photoresist unit; 293, third photoresist unit; 30, second insulation material layer; 31, gate electrode material layer; 32, fourth photoresist unit; 33, fifth photoresist unit.

### DETAILED DESCRIPTION OF PREFERRED EMBODIMENTS

Preferred embodiments of the present invention are described with accompanying drawings as follows introduce a person of ordinary skill in the art the technical contents of the present invention completely such that examples are used to prove that the present invention can be embodied. As such the published technologies of the present invention are made clearer such that a person of ordinary skill in the art can better understand the way to embody the present invention. However, the present invention can be embodied by embodiments of various forms, and the protective scope of the present invention is not only limited in the mentioned embodiment herein, and explanation of the following embodiments is not for limiting the scope of the present invention.

The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention.

In the drawings, elements with the same structures are indicated with the same numerals, and elements with similar structures or functions are indicated with similar numerals. Furthermore, for convenience of understanding and description, the dimension and thickness of each assembly in the drawings are depicted at arbitrarily, and the present invention has no limit to the dimension and thickness of each assembly.

The present application provides a display device comprising a display panel 100.

### Embodiment 1

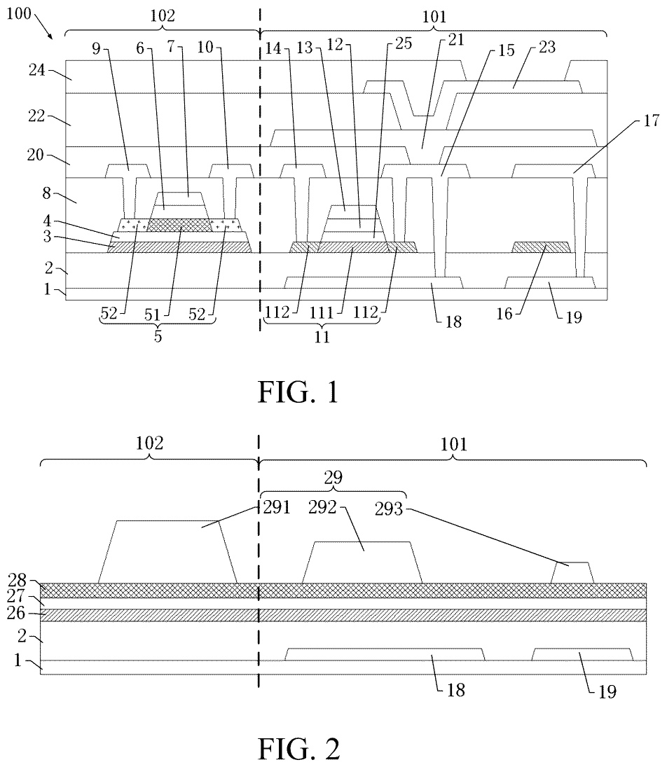

With reference to FIG. 1, the display panel 100 comprises a display region 101 and a gate on array (GOA) region 102 located on at least one side of the display region 101.

The display panel 100 comprises: a substrate 1, a buffer layer 2, a first semiconductor layer 3, a first insulation layer 4, a first active layer 5, a second insulation layer 6, a first gate electrode 7, an interlayer insulation layer 8, a first source electrode 9, a first drain electrode 10, a second active layer 11, a third insulation layer 12, a second gate electrode 13, a second source electrode 14, a second drain electrode 15, a first electrode plate 16, a second electrode plate 17, a first light shielding layer 18, a second light shielding layer 19, a passivation layer 20, a conductive layer 21, a planarization layer 22, a pixel electrode 23, and a pixel definition layer 24.

The substrate 1 is disposed in the display region 101 and the GOA region 102. Material of the substrate 1 comprises glass, polyimide, polycarbonate, polyethylene terephthalate, and polyethylene naphthalate (PEN). In the present embodiment, the material of the substrate 1 is glass.

The buffer layer 2 is disposed on the substrate 1 and is disposed in the display region 101 and the GOA region 102. The buffer layer 2 is mainly configured to perform a buffer function, and material of the buffer layer 2 can be SiOx, SiNx, SiNOx, a combination structure of SiNx and SiOx, or a combination structure of SiOx, SiNx, and SiOx. In the present embodiment, the buffer layer 2 comprises a first buffer layer (not shown in the figures) and a second buffer layer (not shown in the figures) stacked on each other. Material of the first buffer layer is SiNx, and a thickness of the first buffer layer is 1000 A. Material of the second buffer layer is SiOx, and a thickness of the second buffer layer is 3000 A.

The first semiconductor layer 3 is disposed on a side of the buffer layer 2 away from the substrate 1, is located in the GOA region 102, and is disposed to correspond to the first active layer 5. Material of the first semiconductor layer 3 is oxide, and can be IGZO, IGTO, etc. In the present embodiment, the material of the first semiconductor layer 3 is IGZO. A film thickness of the first semiconductor layer 3 ranges from 200 A to 400 A. In the present embodiment, the film thickness of the first semiconductor layer 3 is 300 A.

The first insulation layer 4 is disposed on a side of the first semiconductor layer 3 away from the substrate 1, is disposed to correspond to the first semiconductor layer 3, and is located in the GOA region 102. Material of the first insulation layer 4 can be SiOx, SiNx, SiNOx, a combination structure of SiNx and SiOx, or a combination structure of SiOx, SiNx, and SiOx.

The first active layer 5 is disposed on a side of the first insulation layer 4 away from the substrate 1 and is located in the GOA region 102. Ingredients of the first active layer 5, according to mole percent, comprise: indium zinc oxide ranging from 93 mol % to 99.5 mol %; lanthanide series element ranging from 0.5 mol % to 5 mol %; and scandium ranging from 0 mol % to 2 mol %. The present embodiment utilizes a lanthanide series element and scandium co-doped indium zinc oxide to manufacture oxide as the first active layer 5 of the GOA region 102. The lanthanide series element suppresses formation of excessive oxygen vacancies, and serves as a conversion medium under blue light with low charge transfer transition energy, which can extremely improve stability of the thin film transistor in which the first active layer 5 of the GOA region 102 exists on the basis without influencing the mobility such that high mobility and high stability of the thin film transistor of the GOA region 102 are balanced. Scandium is an excellent oxygen binder that can suppress formation of excessive oxygen vacancies. An electrical potential of a standard electrode of Scandium is comparatively low (−2.36), and an electronegativity of scandium is low (˜1.3). a bonding strength of Sc—O (680 kJ mol−1) is greater than that of In—O (348 KJ mol−1). Sc₃⁺ ions doped in In₂O₃ has the same valence state as that of In3+ ions and would not generate an excessive carrier, and therefore Sc₃⁺ ions can control carrier concentration. Also, Sc₂O₃ and In₂O₃ have the same Bixbyite structure and can reduce defects due to lattice mismatching, maintain lattice matching, and further improve the stability of the thin film transistor in which the first active layer 5 of the GOA region 102 is located such that the thin film transistor of the GOA region 102 balances high mobility and high stability.

The first active layer 5 comprises a first channel part 51 and first conductive parts 52 connected to two ends of the first channel part 51 respectively.

The second insulation layer 6 is disposed on the first active layer 5, is disposed to correspond to the first channel part 51, and is located in the GOA region 102. Material of the second insulation layer 6 can be SiOx, SiNx, SiNOx, or a combination structure of SiNx and SiOx or a combination structure of SiOx, SiNx, and SiOx. In the present embodiment, material of the second insulation layer 6 is SiOx. A film thickness of the second insulation layer 6 ranges from 1000 A to 1500 A. In the present embodiment, a film thickness of the second insulation layer 6 is 1200 A.

The first gate electrode 7 is disposed on a side of the second insulation layer 6 away from the substrate 1, is disposed to correspond to the first channel part 51, and is located in the GOA region 102. Material of the first gate electrode 7 is metal. Material of the first gate electrode 7 can be Mo, a combination structure of Mo and Al, or a combination structure of Mo and Cu, a combination structure of Mo, Cu, and IZO, a combination structure of IZO, Cu, and IZO, a combination structure of Mo, Cu, and ITO, a combination structure of Ni, Cu, and Ni, a combination structure of MoTiNi, Cu, and MoTiNi, a combination structure of NiCr, Cu, and NiCr, or CuNb. A film thickness of the first gate electrode 7 ranges from 3000 A to 5000 A.

The interlayer insulation layer 8 covers the first gate electrode 7, the second gate electrode 13, the first active layer 5, and the second active layer 11. The interlayer insulation layer 8 is mainly configured to prevent the first gate electrode 7 from contacting the first source electrode 9 or the first drain electrode 10 and resulting in a short circuit phenomenon, and is also configured to prevent the second gate electrode 13 from contacting the second source electrode 14 or the second drain electrode 15 and resulting in a short circuit phenomenon. Material of the interlayer insulation layer 8 can be SiOx, SiNx, SiNOx. In the present embodiment, the interlayer insulation layer 8 comprises a first interlayer insulation layer (not shown in the figures) and a second interlayer insulation layer (not shown in the figures) stacked on each other. Material of the first interlayer insulation layer is SiOx, and material of the second interlayer insulation layer is SiNx. A film thickness of the interlayer insulation layer 8 ranges from 3000 A to 6000 A.

The first source electrode 9 is disposed on the interlayer insulation layer 8, is electrically connected to one of the first conductive parts 52, and is located in the GOA region 102. The first drain electrode 10 is disposed in the same layer with the first source electrode 9, is electrically connected to the other of the first conductive parts 52 and is located in the GOA region 102. Material of the first source electrode 9 and the first drain electrode 10 is metal. In the present embodiment, the first source electrode 9 and the first drain electrode 10 are lamination structures of MoTi and Cu. A film thickness of each of the first source electrode 9 and the first drain electrode 10 ranges from 2000 A to 4000 A.

The second active layer 11 is disposed in the same layer with the first semiconductor layer 3 and is located in the display region 101. The second active layer 11 comprises a second channel part 111 and second conductive parts 112 connected to two ends of the second channel part 111. Material of the first semiconductor layer 3 is the same as material of the second channel part 111. Namely, both the first semiconductor layer 3 and the second channel part 111 are not conductivized, thereby able to use the same mask to manufacture and form the second active layer 11 and the first semiconductor layer 3, thereby abler to save masks and simplify processes.

The third insulation layer 12 is disposed on a side of the second active layer 11 away from the substrate 1 and is disposed to correspond to the second channel part 111. In the present embodiment, the second insulation layer 6 and the third insulation layer 12 have the same material, and are disposed in the same layer, thereby able to use the same mask to manufacture and form the second insulation layer 6 and the third insulation layer 12, saving masks and simplifying processes.

In the present embodiment, the display panel 100 further comprises a fourth insulation layer 25. The fourth insulation layer 25 is disposed between the second active layer 11 and the third insulation layer 12 and is disposed to correspond to the second channel part 111. In the present embodiment, the fourth insulation layer 25 and the first insulation layer 4 have the same material and are disposed in the same layer, thereby able to use the same mask to manufacture and form the first insulation layer 4 and the fourth insulation layer 25, saving masks, and simplifying processes. In other embodiment, the fourth insulation layer 25 can also be removed according to actual demands.

The second gate electrode 13 is disposed on a side of the third insulation layer 12 away from the substrate 1 and is disposed to correspond to the second channel part 111. The first gate electrode 7 and the second gate electrode 13 have the same material and are disposed in the same layer, thereby able to use the same mask to manufacture and form the first gate electrode 7 and the second gate electrode 13, saving masks, and simplifying processes.

The second source electrode 14 is disposed in the same layer with the first source electrode 9, is electrically connected to one of the second conductive parts 112, and is located in the display region 101. The second drain electrode 15 is disposed in a same layer with the second source electrode 14, is electrically connected to the other of the second conductive parts 112, and is located in the display region 101.

The first electrode plate 16 is disposed in a same layer with the first semiconductor layer 3, is located in the display region 101, and is disposed on a side of the second active layer 11 away from the first semiconductor layer 3. The first electrode plate 16 and the second conductive parts 112 have the same material. Namely, the first electrode plate 16 and the second conductive parts 112 are conductivized, thereby able to use the same mask to manufacture and form the second active layer 11 and the first electrode plate 16, saving masks, and simplifying processes.

The second electrode plate 17 is disposed in the same layer with the first source electrode 9, is disposed to correspond to the first electrode plate 16, and is located in the display region 101. The second electrode plate 17 is disposed to correspond to the first electrode plate 16 to form a capacitor.

In the present embodiment, the first source electrode 9, the first drain electrode 10, the second source electrode 14, the second drain electrode 15 and the second electrode plate 17 have the same material, thereby able to use the same mask to manufacture the first source electrode 9, the first drain electrode 10, the second source electrode 14, the second drain electrode 15 and the second electrode plate 17, saving masks, and simplifying processes.

The first light shielding layer 18 is disposed between the substrate 1 and the buffer layer 2, is disposed to correspond to the second active layer 11, and is located in the display region 101. The first light shielding layer 18 is configured to prevent light from irradiating the second active layer 11, thereby preventing influence to performance of the second active layer 11.

The second light shielding layer 19 is disposed in the same layer with the first light shielding layer 18, is disposed to correspond to the first electrode plate 16, and is located in the display region 101.

The passivation layer 20 is disposed on a side of the interlayer insulation layer 8 away from the substrate 1 and covers the first source electrode 9, the first drain electrode 10, the second source electrode 14, the second drain electrode 15, and the second electrode plate 17. In the present embodiment, the passivation layer 20 comprises a first passivation layer (not shown in the figures) and a second passivation layer (not shown in the figures) stacked on each other. Material of the first passivation layer is SiOx, and material of the second passivation layer is SiNx. A film thickness of the passivation layer 20 ranges from 3500 A to 5000 A.

The conductive layer 21 is disposed on a side of the passivation layer 20 away from the substrate 1 and is located in the display region 101. The conductive layer 21 extends through the passivation layer 20 and is electrically connected to the second drain electrode 15.

The planarization layer 22 is disposed on a side of the passivation layer 20 away from the substrate 1 and partially covers the conductive layer 21.

The pixel electrode 23 is disposed on a side of the planarization layer 22 away from the substrate 1, extends through the planarization layer 22, and is electrically connected to the conductive layer 21.

The pixel definition layer 24 is disposed on a side of the planarization layer 22 away from the substrate 1 and partially covers the pixel electrode 23.

The present embodiment also provides a display panel manufacturing method of the present embodiment. The display panel comprises a display region 101 and a GOA region 102 located on at least one side of the display region 101. The display panel manufacturing method comprises steps as follows.

A step S1 comprises: manufacturing a first light shielding layer 18 and a second light shielding layer 19 on a substrate 1 of the display region 101.

A step S2 comprises: manufacturing a buffer layer 2 on the first light shielding layer 18, the second light shielding layer 19, and the substrate 1.

A step S3 comprises: manufacturing a first semiconductor material layer 26 on the buffer layer 2.

A step S4 comprises: manufacturing a first insulation material layer 27 on the first semiconductor material layer 26.

A step S5 comprises: manufacturing a first active material layer 28 on the first insulation material layer 27.

A step S6 comprises: manufacturing a photoresist layer 29 on the first active material layer 28. The photoresist layer 29 comprises a first photoresist unit 291 located in the GOA region 102, a second photoresist unit 292 located in the display region 101, and a third photoresist unit 293 located in the display region 101.

With reference to FIG. 2, the step S2 manufactures a buffer layer 2 on the first light shielding layer 18, the second light shielding layer 19, and the substrate 1 by a plasma enhancement chemical vapor deposition (PECVD) process. The step S3 manufactures a first semiconductor material layer 26 on the buffer layer 2 by a sputtering process. The step S4 manufactures a first insulation material layer 27 on the first semiconductor material layer 26 by a PECVD process. The step S6 manufactures a photoresist layer 29 on the first active material layer 28 by a half-tone mask process. A thickness of the first photoresist unit 291 is greater than a thickness of the second photoresist unit 292. The thickness of the second photoresist unit 292 is greater than a thickness of the third photoresist unit 293.

A low temperature sol-gel process is used to manufacture the first active material layer 28. The step S5 comprises: dissolving nitric acid indium, zinc acetate, nitric acid terbium, nitric acid scandium in ethylene glycol methyl ether to form a precursor solution, heating and stirring the precursor solution in a temperature from 60° C. to 80° C. by 6 hours to 8 hours to form oxide gel, centrifugal filtering the oxide gel and then spin-coating the oxide gel at a rotational speed from 2000 rpm to 4000 rpm on the first insulation material layer 27 to form a gel-like thin film with a thickness of the gel-like thin film ranging from 200 A to 300 A, placing the gel-like thin film in an oven of 85° C. to 95° C. and performing a pre-annealing process by 3 min to 7 min to remove a solvent, and then performing a post-annealing process by 220° C. to 280° C. to form a first active material layer 28.

In the present embodiment, the step S5 comprises: dissolving nitric acid indium (In(NO₃)₃·nH₂O), zinc acetate (Zn(CH₃COO)₂), nitric acid terbium (Tb(NO₃)₃·nH₂O), nitric acid scandium (ScNO₃)₃·nH₂O) in ethylene glycol methyl ether to form a precursor solution, heating and stirring the precursor solution in a temperature of 70° C. by 7 hours to form oxide gel, the centrifugal filtering the oxide gel and spin coating the oxide gel on the first insulation material layer 27 at a rotation speed of 3000 rpm to form a gel-like thin film wherein a thickness of the gel-like thin film is 250 A, placing the gel-like thin film in an oven of 90° C. and performing a pre-annealing process a by 5 min to remove a solvent, and then performing a post-annealing process at a temperature of 250° C. to form a first active material layer 28.

A step S7 comprises: patterning the first active material layer 28 and the first insulation material layer 27.

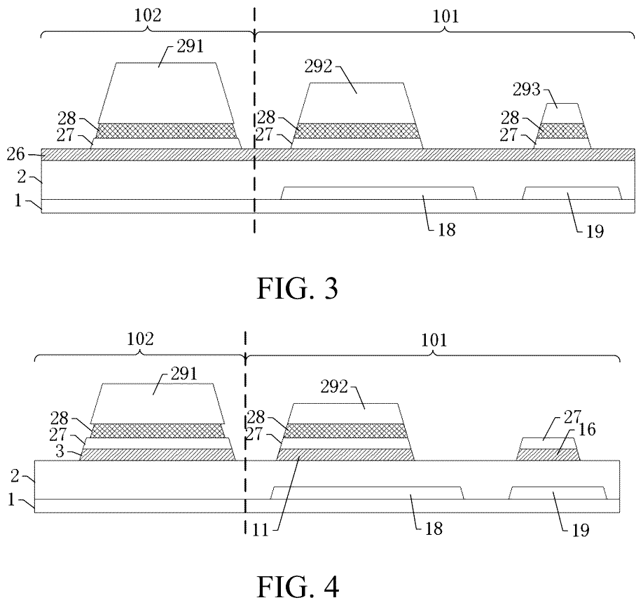

With reference to FIG. 3, the step S7 patterns the first active material layer 28 and the first insulation material layer 27 by one mask lithography process and removes parts of the first active material layer 28 and the first insulation material layer 27 not covered by the first photoresist unit 291, the second photoresist unit 292, and the third photoresist unit 293.

A step S8 comprises: first ashing the photoresist layer 29.

A S9 comprises: etching the first active material layer 28 covered by the third photoresist unit 293 and patterning the first semiconductor material layer 26.

With reference to FIG. 4, the step S8 first ashes the photoresist layer 29 by half-tone mask process, first thins thicknesses of the first photoresist unit 291 and the second photoresist unit 292, and peels all of the third photoresist unit 293 off. The step S9 etches the part of the first active material layer 28 covered by the third photoresist unit 293 out by an oxalic acid etching process, patterns the first semiconductor material layer 26 to form a first semiconductor layer 3, a second active layer 11, and a first electrode plate 16.

A step S10 comprises: removing the first insulation material layer 27 on the first electrode plate 16.

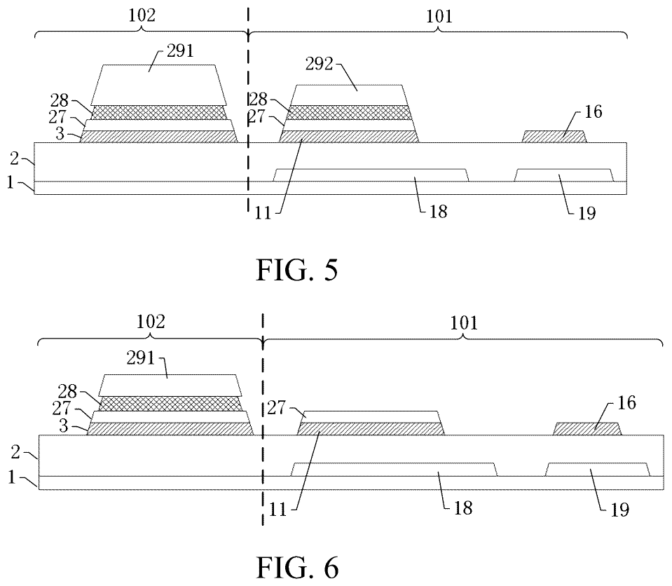

With reference to FIG. 5, the step S10 removes the first insulation material layer 27 on the first electrode plate 16 by a dry-etch process.

A step S11 comprises: second ashing the photoresist layer 29, then removing a part of the first active material layer 28 not covered by the first photoresist unit 291 wherein a part of the first active material layer 28 covered by the first photoresist unit 291 forms a first active layer 5.

With reference to FIG. 6, the step S11 second ashes the photoresist layer 29 by a half-tone mask process, second thins the thickness of the first photoresist unit 291, peels all of the second photoresist unit 292 off, removes a part of the first active material layer 28 not covered by the first photoresist unit 291 by a wet-etching process. A part of the first active material layer 28 covered by the first photoresist unit 291 forms the first active layer 5.

Ingredients of the first active layer, according to mole percent, comprises: indium zinc oxide ranging from 93 mol % to 99.5 mol %; lanthanide series element ranging from 0.5 mol % to 5 mol %; and scandium ranging from 0 mol % to 2 mol %.

As described above, the present embodiment sequentially manufactures the first semiconductor material layer 26, the first insulation material layer 27, and the first active material layer 28, and then manufactures the photoresist layer 29 by one half-tone process. The photoresist layer 29 comprises the first photoresist unit 291 located in the GOA region 102z, the second photoresist unit 292 located in the display region 101, and the third photoresist unit 293 located in the display region 101. A thickness of the first photoresist unit 291 is greater than a thickness of the second photoresist unit 292. The thickness of the second photoresist unit 292 is greater than a thickness of the third photoresist unit 293. The present embodiment uses the photoresist layer 29 to manufacture the first semiconductor layer 3, the second active layer 11, the first electrode plate 16, the first insulation layer 4, the fourth insulation layer 25, and the first active layer 5, thereby able to save masks, simplify production processes, and lower production costs.

A step S12 comprises: peeling the first photoresist unit 291 off, and manufacturing a second insulation material layer 30 on the first active layer 5, the fourth insulation layer 25, the first electrode plate 16, and the buffer layer 2.

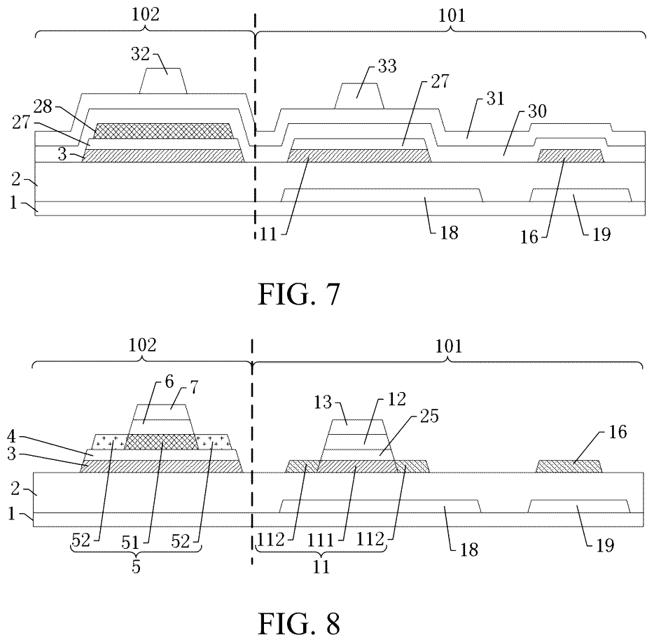

A step S13 comprises: manufacturing a gate electrode material layer 31 on the second insulation material layer 30; manufacturing a fourth photoresist unit 32 on a location of the gate electrode material layer 31 corresponding to the first semiconductor layer 3, and manufacturing a fifth photoresist unit 33 on a location of the gate electrode material layer 31 corresponding to the second active layer 11. With reference to FIG. 7, the step S12 peels the first photoresist unit 291 off, and manufactures a second insulation material layer 30 on the first active layer 5, the fourth insulation layer 25, the first electrode plate 16, and the buffer layer by a PECVD process. The step S13 manufactures a gate electrode material layer 31 on the second insulation material layer 30 by a PVD process, then manufactures a fourth photoresist unit 32 on a location of the gate electrode material layer 31 corresponding to the first semiconductor layer 3, and manufactures on a fifth photoresist unit 33 location of the gate electrode material layer 31 corresponding to the second active layer 11.

A step S14 comprises: patterning the gate electrode material layer 31 to form a first gate electrode 7 and a second gate electrode 13, utilizing the first gate electrode 7 and the second gate electrode 13 to implement self-alignment, dry-etching the second insulation material layer 30 to form a second insulation layer 6 and a third insulation layer 12, conductivizing a part of the first active layer 5 not covered by the second insulation layer 6 to form a first conductive parts 52 wherein a part of the first active layer 5 covered by the second insulation layer 6 forms the first channel part 51, and conductivizing a part of the second active layer 11 not covered by the third insulation layer 12 to form a second conductive parts 112 wherein a part of the second active layer 11 covered by the third insulation layer 12 forms a second channel part 111.

With reference to FIG. 8, the step S14 patterns the gate electrode material layer 31 to form a first gate electrode 7 and a second gate electrode 13, utilizes the first gate electrode 7 and the second gate electrode 13 to implement self-alignment, dry-etches the second insulation material layer 30 to form a second insulation layer 6 and a third insulation layer 12, conductivizes a part of the first active layer 5 not covered by the second insulation layer 6 by He plasma to form a first conductive parts 52 wherein a part of the first active layer 5 covered by the second insulation layer 6 forms the first channel part 51, and conductivizes a part of the second active layer 11 not covered by the third insulation layer 12 by He plasma to form a second conductive parts 112 wherein a part of the second active layer 11 covered by the third insulation layer 12 forms a second channel part 111.

A step S15 comprises: manufacturing an interlayer insulation layer 8 on the first gate electrode 7, the second gate electrode 13, the first electrode plate 16 and the buffer layer 2.

A step S16 comprises: manufacturing a first source electrode 9, a first drain electrode 10, a second source electrode 14, a second drain electrode 15, and a second electrode plate 17 on a side of the interlayer insulation layer 8 away from the substrate 1.

A step S17 comprises: manufacturing a passivation layer 20 on a side of the interlayer insulation layer 8 away from the substrate 1.

A step S18 comprises: manufacturing a conductive layer 21 on a side of the passivation layer 20 away from the substrate 1.

A step S19 comprises: manufacturing a planarization layer 22 on a side of the passivation layer 20 away from the substrate 1.

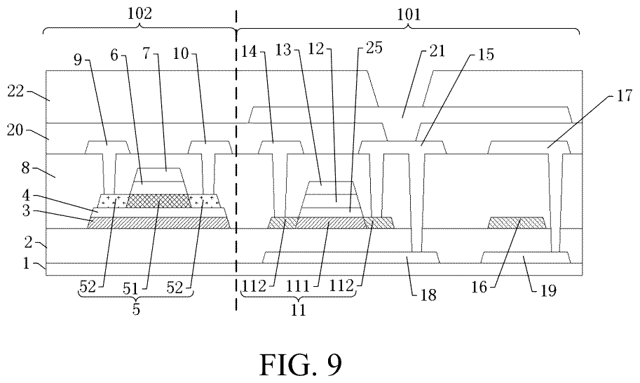

With reference to FIG. 9, the step S17 manufactures a passivation layer 20 on a side of the interlayer insulation layer 8 away from the substrate 1. The passivation layer 20 covers the first source electrode 9, the first drain electrode 10, the second source electrode 14, the second drain electrode 15, and the second electrode plate 17. The step S18 manufactures a conductive layer 21 on a side of the passivation layer 20 away from the substrate 1. The conductive layer 21 is located in the display region 101 and is electrically connected to the second drain electrode 15. The step S19 manufactures a planarization layer 22 on a side of the passivation layer 20 away from the substrate 1. The planarization layer 22 partially covers the conductive layer 21.

A step S20 comprises: manufacturing a pixel electrode 23 on a side of the planarization layer away from the substrate 1.

A step S21 comprises: manufacturing a pixel definition layer 24 on a side of the planarization layer 22 away from the substrate 1.

With reference to FIG. 1, the step S20 manufactures a pixel electrode 23 on a side of the planarization layer away from the substrate 1. The pixel electrode 23 extends through the planarization layer 22 and is electrically connected to the conductive layer 21. The step S21 manufactures a pixel definition layer 24 on a side of the planarization layer 22 away from the substrate 1, and the pixel definition layer 24 partially covers the pixel electrode 23.

In the specification, the specific examples are used to explain the principle and embodiment of the present application. The above description of the embodiments is only used to help understand the method of the present application and its spiritual idea. Meanwhile, for those skilled in the art, according to the present idea of invention, changes will be made in specific embodiment and application. In summary, the contents of this specification should not be construed as limiting the present application.

1. A display panel, comprising: a display region and a gate on array (GOA) region located on at least one side of the display region;
wherein the display panel comprises:
a substrate; and
a first active layer disposed on the substrate and located on the GOA region;
wherein ingredients of the first active layer, according to mole percent, comprise:
indium zinc oxide ranging from 93 mol % to 99.5 mol %; lanthanide series element ranging from 0.5 mol % to 5 mol %; and scandium ranging from 0 mol % to 2 mol %.

2. The display panel according to claim 1, wherein the display panel further comprises:
a first semiconductor layer disposed between the substrate and the first active layer, located in the GOA region, and disposed to correspond to the first active layer; a second active layer disposed in a same layer with the first semiconductor layer and located in the display region, wherein the second active layer comprises a second channel part and second conductive parts connected to two ends of the second channel part respectively; and
a first electrode plate disposed in a same layer with the first semiconductor layer, located in the display region, and disposed on a side of the second active layer away from the first semiconductor layer;
wherein material of the first semiconductor layer is the same as material of the second channel part, and material of the first electrode plate is the same as material of the second conductive parts.

3. The display panel according to claim 2, wherein the first active layer comprises a first channel part and first conductive parts connected to two ends of the first channel part respectively;
the display panel further comprises:
a first insulation layer disposed between the first semiconductor layer and the first active layer and disposed to correspond to the first semiconductor layer;
a second insulation layer disposed on the first active layer and disposed to correspond to the first channel part; and
a third insulation layer disposed on the second active layer and disposed to correspond to the second channel part;
wherein material of the second insulation layer is the same as material of the third insulation layer.

4. The display panel according to claim 3, wherein the second insulation layer is disposed in a same layer with the third insulation layer.

5. The display panel according to claim 3, wherein the display panel further comprises:
a first gate electrode disposed on the second insulation layer and disposed to correspond to the first channel part; and
a second gate electrode disposed on the third insulation layer and disposed to correspond to the second channel part;
wherein material of the first gate electrode is the same as material of the second gate electrode.

6. The display panel according to claim 5, wherein the first gate electrode is disposed in a same layer with the second gate electrode.

7. The display panel according to claim 5, wherein the display panel further comprises:
an interlayer insulation layer covering the first gate electrode, the second gate electrode, the first active layer, and the second active layer;
a first source electrode disposed on the interlayer insulation layer and electrically connected to one of the first conductive parts, and located in the GOA region;
a first drain electrode disposed in a same layer with the first source electrode, electrically connected to another of the first conductive parts, and located in the GOA region;
a second source electrode disposed in a same layer with the first source electrode, electrically connected to one of the second conductive parts, and located in the display region;
a second drain electrode disposed in a same layer with the second source electrode, electrically connected to another of the second conductive parts, and located in the display region; and
a second electrode plate disposed in a same layer with the first source electrode, disposed to correspond to the first electrode plate, and located in the display region;
wherein material of the first source electrode, the first drain electrode, the second source electrode, the second drain electrode, and the second electrode plate is the same.

8. The display panel according to claim 3, wherein the display panel further comprises:
a fourth insulation layer disposed between the second active layer and the third insulation layer and disposed to correspond to the second channel part;
wherein material of the fourth insulation layer and the first insulation layer is the same, and the fourth insulation layer and the first insulation layer are disposed in a same layer.

9. A display panel manufacturing method, wherein a display panel comprises a display region and a gate on array (GOA) region located on at least one side of the display region, and the method comprises a step as follows:
manufacturing a first active layer on a substrate of the GOA region, wherein ingredients of the first active layer, according to mole percent, comprise: indium zinc oxide ranging from 93 mol % to 99.5 mol %; lanthanide series element ranging from 0.5 mol % to 5 mol %; and scandium ranging from 0 mol % to 2 mol %.

10. The display panel manufacturing method according to claim 9, wherein the step of manufacturing a first active layer on a substrate of the GOA region comprises steps as follows:
manufacturing a first semiconductor material layer on the substrate, manufacturing a first insulation material layer on the first semiconductor material layer, and manufacturing a first active material layer on the first insulation material layer;
manufacturing a photoresist layer on the first active material layer by a half-tone mask process, wherein the photoresist layer comprises a first photoresist unit located in the GOA region, a second photoresist unit located in the display region, and a third photoresist unit located in the display region, a thickness of the first photoresist unit is greater than a thickness of the second photoresist unit, and the thickness of the second photoresist unit is greater than a thickness of the third photoresist unit;
removing parts of the first active material layer and the first insulation material layer not covered by the first photoresist unit, the second photoresist unit and the third photoresist unit;
first thinning the thicknesses of the first photoresist unit and the second photoresist unit, removing the third photoresist unit and a part of the first active material layer covered by the third photoresist unit, patterning the first semiconductor material layer to form a first semiconductor layer, a second active layer, and a first electrode plate;
removing the first insulation material layer on the first electrode plate; and
second thinning the thickness of the first photoresist unit, removing the second photoresist unit and a part of the first active material layer covered by the second photoresist unit wherein the first active material layer covered by the first photoresist unit forms a first active layer, and peeling the first photoresist unit off.

11. The display panel manufacturing method according to claim 10, wherein the display panel further comprises:
a first gate electrode disposed on the second insulation layer and disposed to correspond to the first channel part; and
a second gate electrode disposed on the third insulation layer and disposed to correspond to the second channel part;
wherein material of the first gate electrode is the same as material of the second gate electrode.

12. The display panel manufacturing method according to claim 10, wherein the first gate electrode is disposed in a same layer with the second gate electrode.

13. The display panel manufacturing method according to claim 10, wherein the display panel further comprises:
an interlayer insulation layer covering the first gate electrode, the second gate electrode, the first active layer, and the second active layer;
a first source electrode disposed on the interlayer insulation layer and electrically connected to one of the first conductive parts, and located in the GOA region;
a first drain electrode disposed in a same layer with the first source electrode, electrically connected to another of the first conductive parts, and located in the GOA region;
a second source electrode disposed in a same layer with the first source electrode, electrically connected to one of the second conductive parts, and located in the display region;
a second drain electrode disposed in a same layer with the second source electrode, electrically connected to another of the second conductive parts, and located in the display region; and
a second electrode plate disposed in a same layer with the first source electrode, disposed to correspond to the first electrode plate, and located in the display region;
wherein material of the first source electrode, the first drain electrode, the second source electrode, the second drain electrode, and the second electrode plate is the same.

14. The display panel manufacturing method according to claim 10, wherein the display panel further comprises:
a fourth insulation layer disposed between the second active layer and the third insulation layer and disposed to correspond to the second channel part;
wherein material of the fourth insulation layer and the first insulation layer is the same, and the fourth insulation layer and the first insulation layer layer are disposed in a same layer.

15. A display panel, comprising: a display region and a gate on array (GOA) region located on at least one side of the display region;
wherein the display panel comprises:
a substrate; and
a first active layer disposed on the substrate and located on the GOA region;
wherein ingredients of the first active layer, according to mole percent, comprise:
indium zinc oxide ranging from 93 mol % to 99.5 mol %; lanthanide series element ranging from 0.5 mol % to 5 mol %; and scandium ranging from 0 mol % to 2 mol %;
wherein the display panel further comprises:
a first semiconductor layer disposed between the substrate and the first active layer, located in the GOA region, and disposed to correspond to the first active layer; a second active layer disposed in a same layer with the first semiconductor layer and located in the display region, wherein the second active layer comprises a second channel part and second conductive parts connected to two ends of the second channel part respectively; and
a first electrode plate disposed in a same layer with the first semiconductor layer, located in the display region, and disposed on a side of the second active layer away from the first semiconductor layer;
wherein material of the first semiconductor layer is the same as material of the second channel part, and material of the first electrode plate is the same as material of the second conductive parts;
wherein the first active layer comprises a first channel part and first conductive parts connected to two ends of the first channel part respectively;
the display panel further comprises:
a first insulation layer disposed between the first semiconductor layer and the first active layer and disposed to correspond to the first semiconductor layer;
a second insulation layer disposed on the first active layer and disposed to correspond to the first channel part; and
a third insulation layer disposed on the second active layer and disposed to correspond to the second channel part;
wherein material of the second insulation layer is the same as material of the third insulation layer;
wherein the second insulation layer is disposed in a same layer with the third insulation layer;
wherein the display panel further comprises:
a first gate electrode disposed on the second insulation layer and disposed to correspond to the first channel part; and
a second gate electrode disposed on the third insulation layer and disposed to correspond to the second channel part;
wherein material of the first gate electrode is the same as material of the second gate electrode;

16. The display panel according to claim 15, wherein the first gate electrode is disposed in a same layer with the second gate electrode.

17. The display panel according to claim 15, wherein the display panel further comprises:
an interlayer insulation layer covering the first gate electrode, the second gate electrode, the first active layer, and the second active layer;
a first source electrode disposed on the interlayer insulation layer and electrically connected to one of the first conductive parts, and located in the GOA region;
a first drain electrode disposed in a same layer with the first source electrode, electrically connected to another of the first conductive parts, and located in the GOA region;
a second source electrode disposed in a same layer with the first source electrode, electrically connected to one of the second conductive parts, and located in the display region;
a second drain electrode disposed in a same layer with the second source electrode, electrically connected to another of the second conductive parts, and located in the display region; and
a second electrode plate disposed in a same layer with the first source electrode, disposed to correspond to the first electrode plate, and located in the display region;
wherein material of the first source electrode, the first drain electrode, the second source electrode, the second drain electrode, and the second electrode plate is the same.

18. The display panel according to claim 15, wherein the display panel further comprises:
a fourth insulation layer disposed between the second active layer and the third insulation layer and disposed to correspond to the second channel part;
wherein material of the fourth insulation layer and the first insulation layer is the same, and the fourth insulation layer and the first insulation layer layer are disposed in a same layer.
